(19) United States
(12) Patent Application Publication
(10) Pub. No.: US 2007/0009660 A1
(43) Pub. Date: Jan. 11, 2007

(54) Method for local application of diffusion aluminide coating

(76) Inventors: Akiko Sasaki, Tokyo (JP); Narihito Ohi, Tokyo (JP); Shigekazu Muneda, Tokyo (JP); Hideo Takahashi, Tokyo (JP)

Correspondence Address: GRIFFIN BUTLER WHISENHUNT & SZIPL LLP;SUITE PH-1, 2300 NINTH STREET SOUTH, ARLINGTON, VA, 222042396, US

(21) Appl. No.: 10/552,719

(22) PCT Filed: Aug. 8, 2005
(86) PCT No.: PCT/JP05/14495

§ 371 Date: Oct. 11, 2005

(30) Foreign Application Priority Data
Jan. 19, 2005 (JP) 011241/2005

(51) Int. Cl. B05D 3/00; C23C 16/00

(52) U.S. Cl. 427/252; 427/140

(57) ABSTRACT

A method includes a component preparation step 10 of exposing local areas (damaged areas of an existing coating) of a base material of a metal component 1 to be coated, and roughening a surface of the base material to a desired surface roughness, a slurry preparation step 12 of preparing a coating slurry that contains a halide activator, a water soluble organic binder, and powder of an aluminum-containing intermetallic compound 3, an application and drying step 14 of applying the coating slurry to the damaged areas of the metal component, and then drying the areas, a packing step 16 of packing the metal component in a heat-resistant container filled with alumina powder, a diffusion treatment step 18 of retaining the heat-resistant container at high temperature in an inert atmosphere or a reducing atmosphere to diffuse aluminum onto the surface of the metal component, and a cleaning step 20 of taking out the metal component from the heat resistant container, and removing a slag from the surface of the metal component.

### BACKGROUND OF THE INVENTION

1. Technical Field of the Invention

The present invention relates to a method for local application of diffusion aluminide coating, capable of reducing generation of cracks and attaining high oxidation resistance.

2. Description of Related Art

In gas turbines for jet engine or gas turbines for land power generation, it is the common practice to apply antioxidation coating onto the surface of metal components exposed to a high temperature gas (which components will hereinafter be called “high temperature metal components”) such as blade, vane, shroud and combustor in order to improve their oxidation resistance.

Such antioxidation coating is formed by keeping a component to be coated at a predetermined temperature in a condition abundant in a specified element (mainly, aluminum).

High-temperature metal components subjected to the above-described antioxidation coating sometimes suffer damages such as chipping in a portion of the coating during operation of a gas turbine or processing of the components. “Overall re-coating” or “localized coating” has conventionally been applied to such locally damaged high temperature metal components.

“Overall re-coating” is one of the repairing methods of damaged coating by completely removing the entire coating including even the remaining undamaged area and applying coating again. It has high reliability, but is not cost effective. When the damaged area is not so large, “localized coating” is therefore carried out to repair only the damaged area.

One example of such a localized coating method is a method already disclosed by Patent Document 1. This known method comprises attaching an iron-aluminum alloy adhesive tape containing about 55 to 57 wt. % of aluminum to a high temperature metal component to be coated therewith, putting the resulting component in an inert aluminum oxide powder, and retaining it for long hours while heating it at about 1800 to 2000° F. in an inert or reducing atmosphere.

Localized coating methods to be applied particularly to an internal passage or the like are disclosed in Patent Documents 2 and 3.

The method in Patent Document 2 comprises applying a water soluble slurry to an internal passage or the like by injection, drying to remove the water soluble solvent, heating it in a non-oxidizing atmosphere at 1350 to 2250° F. for 4 to 24 hours to diffuse aluminum. In particular, this method is characterized in that the water soluble slurry contains an aluminum source, inert ceramic particles, a halide activator and an aqueous base dispersant.

The method in Patent Document 3 comprises applying a coating slurry, drying to remove water, heating to diffuse aluminum on the surface. This method is characterized in that the coating slurry contains a carrier component composed of water and inorganic gel forming agent, an aluminum source and an oxide dispersant.

Patent Document 1: Japanese Laid-Open Patent Publication No. 2003-41360, “Method for applying diffusion aluminide coating on a selective area of a turbine engine component”

Patent Document 2: U.S. Pat. No. 5,366,765, “AQUEOUS SLURRY COATING SYSTEM FOR ALUMINIDE COATINGS”

Patent Document 3: U.S. Pat. No. 6,497,920, “PROCESS FOR APPLYING AN ALUMINIDE CONTAINING COATING USING AN INORGANIC SLURRY MIX”

There is an eager demand for the development of an outward type diffusion coating, as a localized coating method, which has higher oxidation resistance enough to deal with an increase in the operation temperature of a gas turbine and permits repetition of repair by forming an additive layer outside the base material by diffusion and therefore reducing wastage of the base material.

In the conventional localized coating method as disclosed in Patent Document 1, however, a blue zone which looks blue because of a high aluminum concentration tends to be formed in the vicinity of the surface and during oxidation resistance test (at 1121° C. for 23 hours in the air) or during use of the component, and coating damages such as cracks and chipping frequently appear in the vicinity of the surface, which make the quality of the coating unstable.

The methods as disclosed in Patent Documents 2 and 3 are inevitably costly, because slurry components not essentially necessary such as inert ceramic particles, aqueous base dispersant, inorganic gel forming agent and oxide dispersant must be added to the slurry.

The present invention is made in order to overcome the above-described problems. An object of the present invention is therefore to provide a method for local application of diffusion aluminide coating capable of readily applying coating stable in quality onto an area of a high temperature metal component by using, as an aluminum source, a material having a precisely stable aluminum content, and not using unnecessary slurry components such as inert ceramic particles and oxide dispersant, thereby attaining higher oxidation resistance with less damages, such as cracks and chipping during oxidation resistance test or during use of the component.

### SUMMARY OF THE INVENTION

In the present invention, there is thus provided a method for local application of diffusion aluminide coating on areas of a metal component to be exposed to a high temperature gas, comprising:

a component preparation step of exposing a local area (damaged area of an existing coating) of a base material of a metal component to be coated, and roughening a surface of the base material to a desired surface roughness;

a slurry preparation step of preparing a coating slurry that contains a halide activator, a water soluble organic binder, and powder of an aluminum-containing intermetallic compound;

an applying/drying step of applying the coating slurry to the local areas of the metal component, and then drying the local areas;

a packing step of packing the metal component in a heat-resistant container filled with alumina powder;

a diffusion treatment step of retaining the heat-resistant container at high temperature in an inert atmosphere or a reducing atmosphere to diffuse aluminum onto the surface of the metal component; and

a cleaning step of taking out the metal component from the heat resistant container, and removing a slag from the surface of the metal component.

According to the preferred embodiment of the present invention, TiAl₃ or αTiAl₃ having a theoretical aluminum ratio of 62.8% by weight and containing 0.5% or less impurities is used as the intermetallic compound.

Preferably, the coating slurry is prepared using AlF₃ as the halide activator, and mixing the coating source and the activator at a weight ratio of 93 to 97:3 to 7, while using the water soluble organic binder.

In the applying/drying step, the application and the drying are repeated alternately to obtain a slurry thickness of 0.5 mm or more.

In the diffusion treatment step, the heat-resistant container is retained at 1900 to 2000° F. (about 1038 to 1094° C.) for about 2 to 9 hours.

The metal component is a blade, vane, shroud or combustor of a gas turbine.

According to the method of the present invention, coating with stable quality can be readily applied because a coating slurry is prepared using an aluminum-containing intermetallic compound powder (preferably, TiAl₃ or αTiAl₃), and therefore, an aluminum content is precisely fixed (theoretical ratio: 62.8% by weight).

It has been confirmed by the embodied examples of the present invention that coating with stable quality can be readily applied to a damaged area of a high temperature metal component without using excess slurry components, which are essentially unnecessary, such as inert ceramic particles and oxide dispersant, and the resulting coating has less cracking or chipping after the oxidation resistance test and therefore has high oxidation resistance.

The coating thus obtained is an outward diffusion type, and it has also been confirmed that a reduction amount of the base material of a thin blade or vane can be minimized, and repair can be made in repetition.

### BRIEF DESCRIPTION OF THE DRAWINGS

FIG. 1 shows aluminum source to be used in the present invention;

FIG. 2 is a flow chart of the application method of the present invention;

FIGS. 3A, 3B and 3C are illustrations of the application steps of FIG. 2;

FIGS. 4A and 4B are cross-sectional photographs of the microstructure showing the embodied examples of the present invention; and

FIGS. 5A, 5B, 5C and 5D are the cross-sectional photographs of the microstructure showing another embodied example of the present invention.

### DESCRIPTION OF THE PREFERRED EMBODIMENTS

Preferred embodiments of the present invention will be described based on drawings. In the drawings, common members will be identified by same reference numerals, and overlapping descriptions will be omitted.

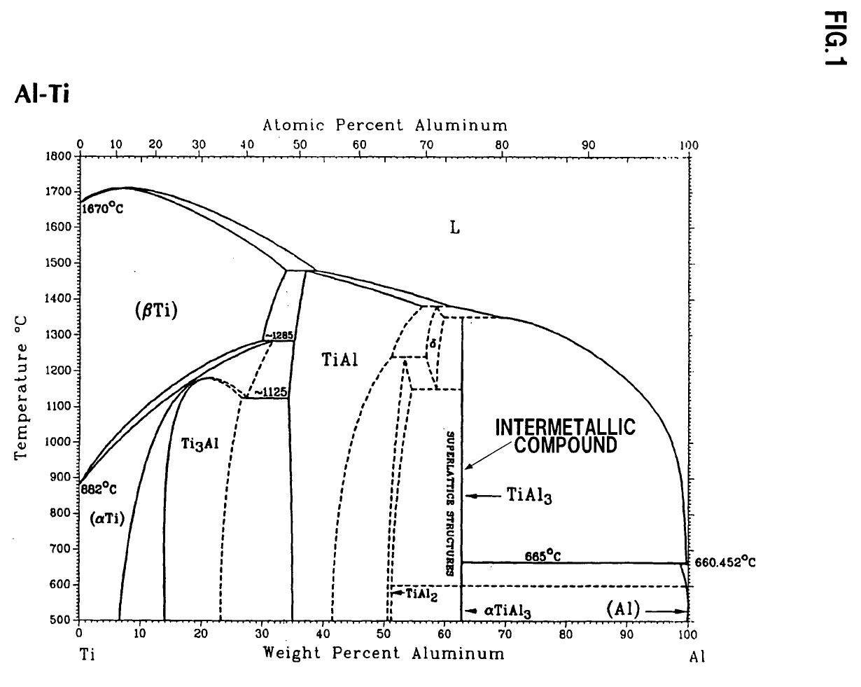

FIG. 1 shows an aluminum source to be used in the present invention. In this diagram, an alloy and an intermetallic compound each containing two elements, that is, aluminum (Al) and titanium (Ti) are shown. A weight percent of aluminum is plotted on the abscissa, while temperature is plotted on the ordinate. Each mark in this figure indicates an alloy or intermetallic compound.

In an alloy, pure metals are solid-solutioned into each other so that they can form a metallic bond. It has disordered atomic arrangement. The term “Ti—Al alloy” generally means titanium in which a certain ratio of aluminum has been solid-solutioned. The content of aluminum is expressed by weight.

In an intermetallic compound, on the other hand, pure metal atoms form a covalent bond at a certain ratio and its atomic arrangement is ordered. Their bonding ratio is fixed and expressed by an atomic ratio such as TiAl₃. Accordingly, the aluminum content in the intermetallic compound is constant and it is 62.8% by weight in the case of TiAl₃.

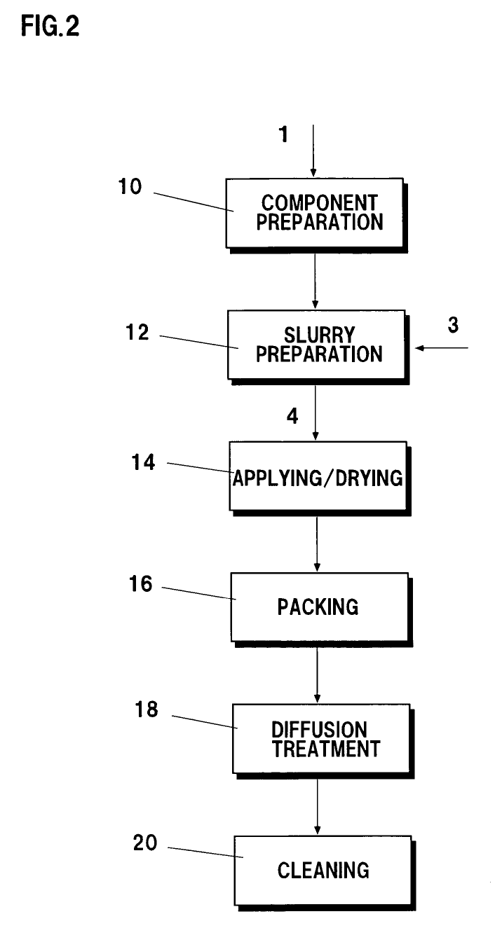

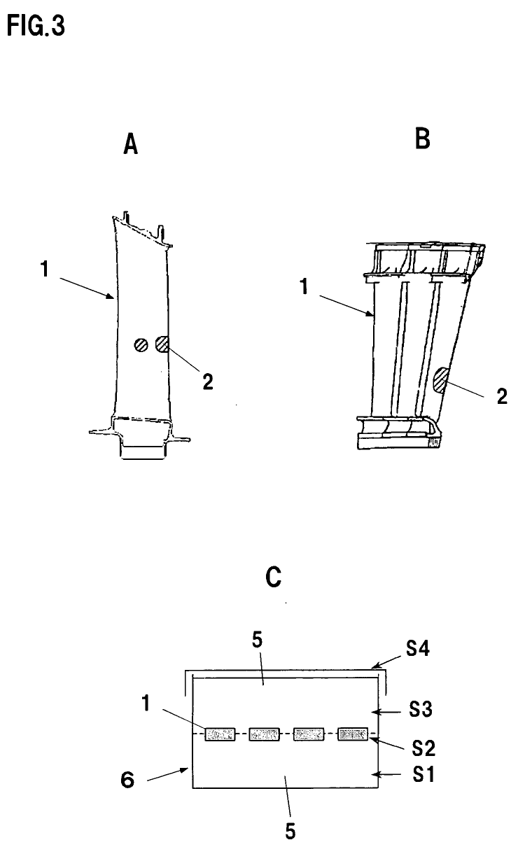

FIG. 2 is a flow chart of the application method of the present invention, and FIG. 3 is an illustration of the steps of this method.

As illustrated in FIG. 2, the method of the present invention is to apply diffusion aluminide coating onto a local area (damaged area of existing coating) of a metal component 1 to be exposed to a high-temperature gas. This method comprises a component preparation step 10, a slurry preparation step 12, an applying/drying step 14, a packing step 16, a diffusion treatment step 18 and a cleaning step 20. These steps are repeated in the order shown in FIG. 2 in accordance with necessity.

The metal component 1 to which coating is applied is, for example, a high temperature metal component such as blade, vane, shroud and combustor of a gas turbine. The present invention is not limited to them, but can be generally applied to high temperature metal components exposed to a high temperature gas.

In the component preparation step 10, a local area (damaged area of conventional coating) of a base material of a metal component 1 to which coating is applied is exposed and the surface is roughened to a desired surface roughness to facilitate application of the coating. This step is composed of, for example, three steps of blending, washing for degreasing, and blasting.

In the blending step, the damaged area of coating is blended as illustrated in FIG. 3A or 3B. When damages in coating of the metal component 1 such as turbine blade or vane appears during operation, only the damaged area 2 marked with diagonal lines is blended to remove the original coating completely.

In the washing step for degreasing, the surface of the base material thus blended is degreased by washing.

In the blasting step, the surface is roughened to facilitate adhesion of the slurry thereto.

In the slurry preparation step 12, a coating slurry 4 containing powder of an aluminum-containing intermetallic compound 3, halide activator, and water soluble organic binder is prepared. Preferably, as the intermetallic compound 3, TiAl₃ or αTiAl₃ having a theoretical aluminum ratio of 62.8% by weight and containing 0.5% or less impurities is used as the intermetallic compound 3. As the halide activator, AlF₃ is employed. The coating source and activator are mixed at a weight ratio of 93 to 97:3 to 7 (preferably, 95:5). By using the water soluble organic binder, the coating slurry is prepared.

It is not necessary to carry out the component preparation step 10 and slurry preparation step 12 in this order. They may be performed in parallel or in the reversed order.

In the applying/drying step 14, the coating slurry 4 is applied to local areas of the metal component 1, followed by drying. In this step, after application, the resulting layer is dried, and this applying and drying are repeated alternately to give a slurry thickness of 0.5 mm or more. The slurry thickness may be changed as need.

In the packing step 16, the metal component 1 is packed in a heat resistant container 6 filled with alumina powder 5. Specifically, as illustrated in FIG. 3C, the heat resistant container 6 (box) is filled up to about half of the container 6 with alumina powder 5 (S1), the metal components 1 (products) are arranged at equal intervals (S2), alumina powder is further packed in the container (S3), and then the container is covered with a lid. The heat resistant container 6 (box) is made of a heat resistant material which does not greatly deform or change in quality in the diffusion treatment step 18.

In the diffusion treatment step 18, the heat resistant container 6 is maintained at high temperature in an inert atmosphere or a reducing atmosphere to diffuse aluminum to the surface of the metal component. In this diffusion treatment step 18, the temperature is kept at 1900 to 2000° F. (about 1038 to 1094° C.) for about 2 to 9 hours (preferably 4 hours). For the inert atmosphere or reducing atmosphere, the heat resistant container 6 is put in an inert gas (He, Ar or the like) or a reducing gas (such as hydrogen). If necessary, an inert gas or reducing gas may be introduced directly into the heat resistant container 6.

In the cleaning step 20, the metal component 1 is taken out from the heat resistant container 6, and the slag is removed from its surface. This step is composed of, for example, two steps of unpacking and blasting.

In the unpacking step, the product (metal component 1) is taken out from the alumina powder after completion of the diffusion. In the blasting step, blasting is performed to remove the slag from the coating surface.

### EMBODIED EXAMPLE 1

For the formation of outward type diffusion coating with higher oxidation resistance, the following coating source and activator were employed.

Coating source: TiAl₃ powder

Activator: halide (AlF₃)

As the intermetallic compound, TiAl₃ having a theoretical aluminum ratio of 62.8% by weight and containing 0.5% or less impurities was used. The coating source and activator were mixed at a weight ratio of 95:5, and a slurry was prepared using a water soluble binder.

The slurry thus prepared was applied to a damaged area of a metal component. After drying, the metal component was inserted in alumina powder and maintained at 1900 to 2000° F. (1038 to 1094° C.) for 4 hours in an inert gas or hydrogen atmosphere.

The other steps were performed as described above.

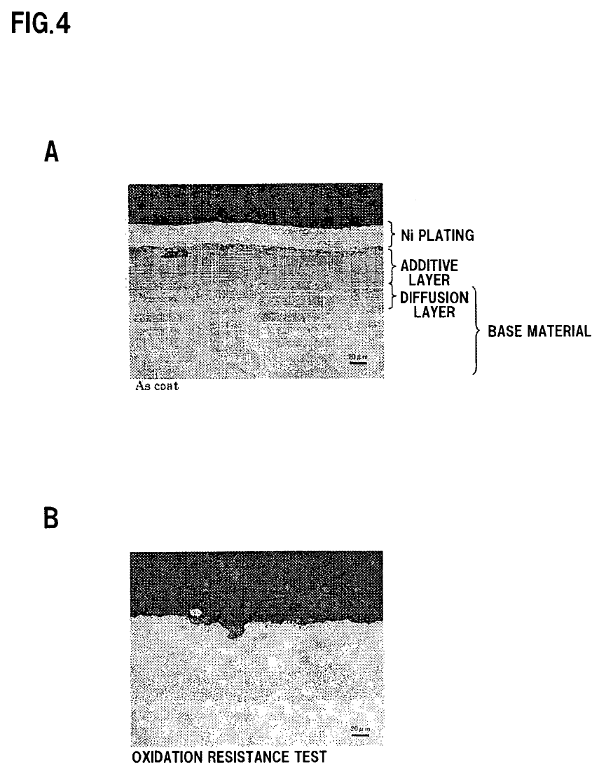

FIGS. 4A and 4B are cross-sectional photographs of the microstructure showing the example of the present invention. FIG. 4A is a cross-sectional photograph of the coating microstructure obtained in the above-described method of the present invention, and FIG. 4B is a cross-sectional photograph of the coating microstructure after the oxidation resistance test. The oxidation resistance test was carried out under conventional test conditions (at 1121° C. for 23 hours in the air).

FIG. 4A shows an Ni-plated surface. It has been understood from this photograph that a diffusion layer of 30 μm thick is formed in the vicinity of the surface of the base material and, at the outer side of this diffusion layer, an additive layer of about 40 μm thick is formed. This suggests that the coating obtained by the invention method is outward diffusion type, can minimize a reduction amount of a base material of a thin blade or vane to the minimum, and therefore permits repeated repair.

It has been confirmed from the cross-sectional microstructure photograph of FIG. 4B after oxidation resistance test that the diffusion layer and additive layer grow after the test but they are free from defects such as cracks and show excellent oxidation resistance.

### EMBODIED EXAMPLE 2

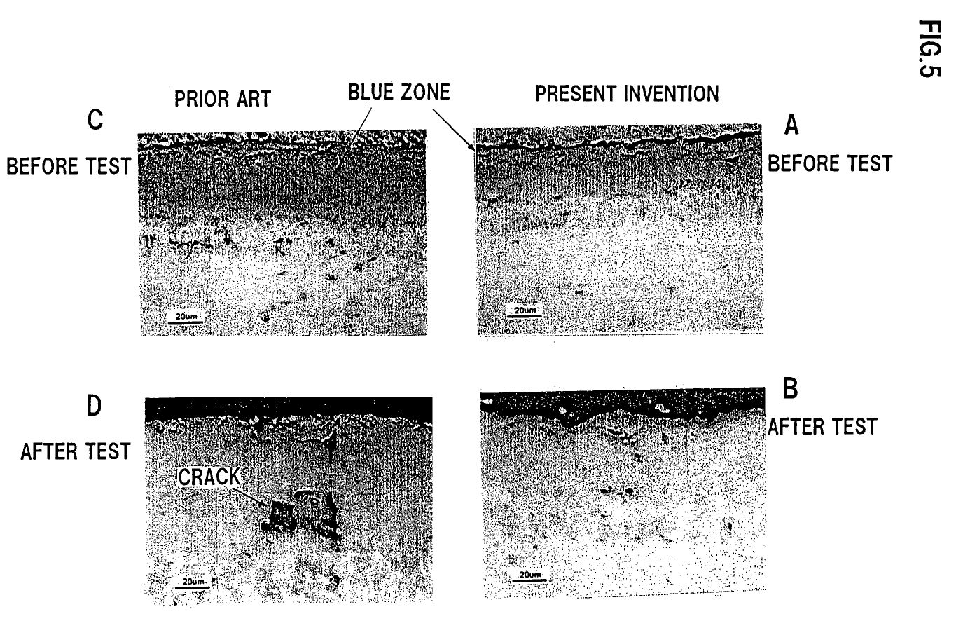

FIGS. 5A, 5B, 5C and 5B are cross-sectional photographs of the microstructure showing other examples of the present invention. In these drawings, FIG. 5A is a cross-sectional photograph of the microstructure of another coating obtained by the above-described invention method, and FIG. 5B is a cross-sectional photograph of the coating microstructure after oxidation resistance test. FIG. 5C is a cross-sectional photograph of the coating microstructure obtained by the above-described conventional method, and FIG. 5D is a cross-sectional photograph of the coating after oxidation resistance test. The oxidation resistance test was carried out under conventional test conditions (at 1121° C. for 23 hours in the air).

When only oxidation resistance is taken into account, an aluminum concentration is preferably higher. When an aluminum concentration is excessively high, however, the coating becomes very brittle, chipping or cracks tend to appear, and the coating shows less oxidation resistance. Accordingly, a well-balanced aluminum concentration is required. In general, a region of an additive layer having an aluminum concentration of 27% or more looks blue on the microstructure photograph so that it is called “blue zone”. It provides an indication of an aluminum concentration.

The blue zone can be found clearly from the cross-sectional microstructure photograph of FIG. 5C showing the conventional coating after the test, and it occupies most of the additive layer, which suggests that this coating has a high aluminum concentration and tends to be cracked.

A blue zone can be found from FIG. 5A showing the coating according to the present invention, but it is very narrow. It appears only in the surface portion of the additive layer. Its concentration is lower than that of FIG. 5C, suggesting that this coating is more stable with a low aluminum concentration.

A large number of cracks which look black are found from the cross-sectional microstructure photograph of FIG. 5D showing the conventional coating after the test. From FIG. 5B showing the coating according to the present invention, on the other hand, no such cracks were found, suggesting that the coating has sufficient oxidation resistance.

As described above, a coating of about 50 to 60 μm thick is formed by the method of the present invention and this coating is found to have excellent oxidation resistance. The coating is an outward diffusion type so that a reduction amount of the base material of a thin blade or vane can be minimized, meaning that it permits repeated repair.

The present invention is not limited to the above-described examples or embodiments. It is needless to say that various modificaions may be made without departing from the scope of the invention.

1. A method for local application of diffusion aluminide coating on areas of a metal component to be exposed to a high temperature gas, comprising:
a component preparation step of exposing local areas (damaged areas of an existing coating) of a base material of a metal component to be coated, and roughening a surface of the base material to a desired surface roughness;
a slurry preparation step of preparing a coating slurry that contains a halide activator, a water soluble organic binder, and powder of an aluminum-containing intermetallic compound;
an applying/drying step of applying the coating slurry to the local areas of the metal component, and then drying the local areas;
a packing step of packing the metal component in a heat-resistant container filled with alumina powder;
a diffusion treatment step of retaining the heat-resistant container at high temperature in an inert atmosphere or a reducing atmosphere to diffuse aluminum onto the surface of the metal component; and
a cleaning step of taking out the metal component from the heat resistant container, and removing a slag from the surface of the metal component.

2. A method for local application of diffusion aluminide coating according to claim 1, wherein TiAl₃ or αTiAl₃ having a theoretical aluminum ratio of 62.8% by weight and containing 0.5% or less impurities is used as the intermetallic compound.

3. A local application method of diffusion aluminide coating according to claim 2, wherein the coating slurry is prepared using AlF₃ as the halide activator, and mixing the coating source and the activator at a weight ratio of 93 to 97:3 to 7, while using the water soluble organic binder.

4. A method for local application of diffusion aluminide coating according to claim 1, wherein in the applying/drying step, the applying and the drying are repeated alternately to obtain a slurry thickness of 0.5 mm or more.

5. A method for local application of diffusion aluminide coating according to claim 1, wherein in the diffusion treatment step, the heat-resistant container is retained at 1900 to 2000° F. (about 1038 to 1094° C.) for about 2 to 9 hours.

6. A method for local application of diffusion aluminide coating according to claim 1, wherein the metal component is a blade, vane, shroud or combustor of a gas turbine.
